(19) United States
(12) Patent Application Publication
(10) Pub. No.: US 2022/0375763 A1
(43) Pub. Date: Nov. 24, 2022

(54) SEMICONDUCTOR DEVICE AND ETCHING METHOD

(71) Applicant: SONY SEMICONDUCTOR SOLUTIONS CORPORATION, Kanagawa (JP)

(72) Inventors: Akiko HIRATA, Kanagawa (JP); Masanaga FUKASAWA, Kanagawa (JP)

(73) Assignee: SONY SEMICONDUCTOR SOLUTIONS CORPORATION, Kanagawa (JP)

(21) Appl. No.: 17/793,333

(22) PCT Filed: Jun. 15, 2020
(86) PCT No.: PCT/JP2020/023359

§ 371 Date: Jul. 15, 2022

Related U.S. Application Data
(60) Provisional application No. 62/968,016, filed on Jan. 30, 2020.

(51) Int. Cl. H01L 21/311; H01L 23/485

(52) U.S. Cl. CPC H01L 21/31116; H01L 23/485

(57) ABSTRACT

Provided is an etching method that can ameliorate defects caused by etching during processing contact holes in a semiconductor device. The etching method includes attracting and adhering a first polymerization film onto an insulating film disposed on a semiconductor layer that contains silicon by plasma of a first gas, removing the first polymerization film by plasma of a second gas, and simultaneously, oxidizing an upper surface of the insulating film to form an alteration layer, attracting and adhering a second polymerization film onto the alteration layer by plasma of a third gas, and removing the second polymerization film and the alteration layer by plasma of a fourth gas.

### TECHNICAL FIELD

The technique of the present disclosure (the present technique) relates to a semiconductor device and an etching method.

### BACKGROUND ART

Conventionally, various methods have been studied as etching methods of semiconductor devices. For example, PTL 1 discloses an etching method for removing each atomic layer by repeating a procedure of generating plasma of fluorocarbon gas and a procedure of generating plasma of argon (Ar) gas using a silicon oxide film (SiO₂ film) as a film to be etched.

### CITATION LIST

### Patent Literature

[PTL 1]
JP 2017-183688 A

### SUMMARY

### Technical Problem

By the way, a silicon nitride film (SiN film) is used as an etching stopper at the time of processing a contact hole of a semiconductor device, and the like, in some cases. However, a recess part (recess) is formed in a semiconductor layer under the SiN film by the over-etching of the SiN film, and residual defects occur at the bottom of the recess, and dark current may increase in some cases.

The present technique has an object to provide a semiconductor device and an etching method capable of decreasing the defects by etching at the time of processing a contact hole of a semiconductor device.

### Solution to Problem

In summary, a semiconductor device according to one aspect of the present technique includes a semiconductor layer containing silicon, a first insulating film that is disposed on the semiconductor layer and has an opening, an electrically conductive layer that is filled in the opening of the first insulating film and has a lower edge that is in contact with the semiconductor layer, and an alteration layer that is disposed between the first insulating film and the electrically conductive layer and contains oxygen.

In summary, an etching method according to one aspect of this technique includes attracting and adhering a first polymerization film onto an insulating film disposed on a semiconductor layer that contains silicon by plasma of a first gas, removing the first polymerization film by plasma of a second gas, oxidizing an upper surface of the insulating film exposed by removing the first polymerization film to form an alteration layer, attracting and adhering a second polymerization film onto the alteration layer by plasma of a third gas, and removing the second polymerization film and the alteration layer by plasma of a fourth gas.

### BRIEF DESCRIPTION OF DRAWINGS

FIG. 1 is a cross-sectional view of a semiconductor device according to a first embodiment.

FIG. 2 is a schematic view of a plasma processing apparatus according to the first embodiment.

FIG. 3 is a flow chart of an etching method of a semiconductor device according to the first embodiment.

FIG. 4 is a process cross-sectional view of an etching method according to the first embodiment.

FIG. 5 is a process cross-sectional view subsequent to FIG. 4 of the etching method according to the first embodiment.

FIG. 6A is a process cross-sectional view subsequent to FIG. 5 of the etching method according to the first embodiment.

FIG. 6B is a partially enlarged view of FIG. 6A.

FIG. 7A is a process cross-sectional view subsequent to FIG. 6A of the etching method according to the first embodiment.

FIG. 7B is a partially enlarged view of FIG. 7A.

FIG. 8A is a process cross-sectional view subsequent to FIG. 7A of the etching method according to the first embodiment.

FIG. 8B is a partially enlarged view of FIG. 8A.

FIG. 9A is a process cross-sectional view subsequent to FIG. 8A of the etching method according to the first embodiment.

FIG. 9B is a partially enlarged view of FIG. 9A.

FIG. 10 is a process cross-sectional view subsequent to FIG. 9A of the etching method according to the first embodiment.

FIG. 11 is a graph showing an Ar ion penetration simulation result.

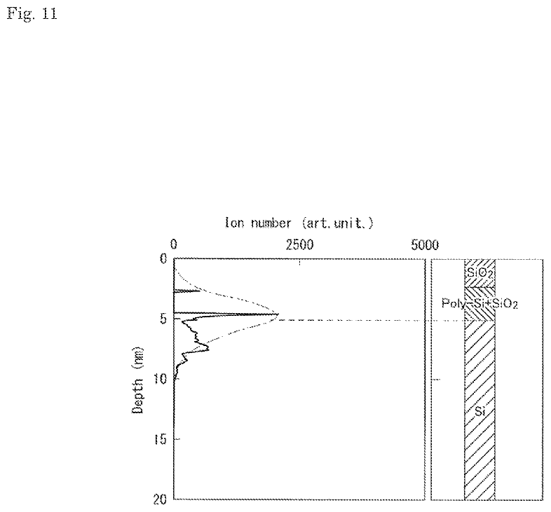

FIG. 12 is a process cross-sectional view of an etching method according to a first comparative example.

FIG. 13 is a process cross-sectional view subsequent to FIG. 12 of the etching method according to the first comparative example.

FIG. 14 is a process cross-sectional view subsequent to FIG. 13 of the etching method according to the first comparative example.

FIG. 15 is a process cross-sectional view of an etching method according to a second comparative example.

FIG. 16 is a process cross-sectional view subsequent to FIG. 15 of the etching method according to the second comparative example.

FIG. 17 is a cross-sectional view of a semiconductor device according to a second embodiment.

FIG. 18 is a cross-sectional view of a semiconductor device according to a third embodiment.

FIG. 19 is a process cross-sectional view of an etching method according to a fourth to sixth embodiments.

FIG. 20 is a cross-sectional view of a semiconductor device according to a fourth embodiment.

FIG. 21 is a cross-sectional view of a semiconductor device according to a fifth embodiment.

FIG. 22 is a cross-sectional view of a semiconductor device according to a sixth embodiment.

FIG. 23 is a block diagram of a solid-state image pickup device according to the seventh embodiment.

FIG. 24 is an equivalent circuit diagram of a pixel illustrating according to the seventh embodiment.

FIG. 25 is a block diagram of an electronic device according to the seventh embodiment.

### DESCRIPTION OF EMBODIMENTS

Hereinafter, the first to seventh embodiments of the present technique will be described with reference to drawings. They will be referred to in the following description. In the illustration of the drawings, the same or similar portions are denoted with the same or similar reference signs. However, it should be noted that the figures are schematic and the relationships between thicknesses and planar dimensions, ratios of thicknesses of respective layers, and the like are different from actual ones. Therefore, specific thicknesses and dimensions should be determined by taking the following descriptions into consideration. In addition, it goes without saying that the drawings include portions where dimensional relationships and ratios differ between the drawings. The advantageous effects described in the present specification are merely exemplary and are not restrictive, and other advantageous effects may be produced.

In the present description, it is to be understood that definitions of directions such as “up” and “down” are merely definitions provided for the sake of brevity and are not intended to limit the technical ideas of the present technique. For example, it is obvious that when an object is observed after being rotated 90°, “up” and “down” are interpreted as being converted into “left” and “right”, and when an object is observed after being rotated 180°, “up” and “down” are interpreted as being inverted.

### First Embodiment

<Structure of Semiconductor Device>

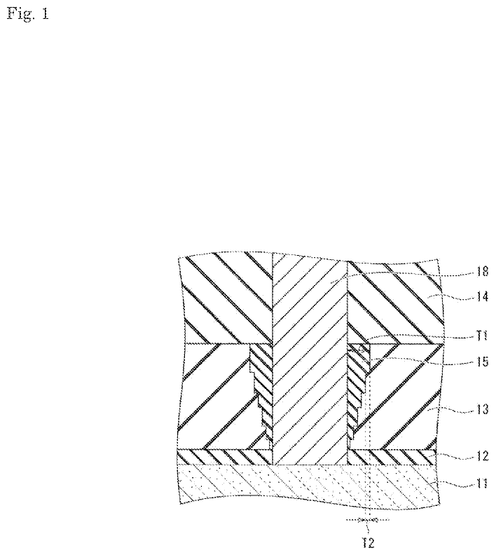

As shown in FIG. 1, the semiconductor device according to the first embodiment includes a semiconductor layer 11 containing silicon (Si), an insulating film (lower layer insulating film) 12 disposed on the semiconductor layer 11, an insulating film (middle layer insulating film) 13 disposed on the lower layer insulating film 12, and an insulating film (upper layer insulating film) 14 disposed on the middle layer insulating film 13.

The semiconductor layer 11 is made of, for example, silicon (Si). The semiconductor layer 11 may be formed of a Si substrate, and may be formed of an epitaxially grown layer epitaxially grown on the Si substrate. The semiconductor layer 11 may be formed of a compound semiconductor such as silicon carbide (SiC) and silicon germanium (SiGe).

For example, the lower layer insulating film 12 is made of a natural oxide film of a silicon oxide film (SiO₂ film). For example, the thickness of the lower layer insulating film 12 is about 1 nm, although it is not limited thereto.

Alternatively, the lower layer insulating film 12 may be omitted, and the semiconductor layer 11 and the middle layer insulating film 13 may be in direct contact with each other.

For example, the middle layer insulating film 13 is formed of a silicon nitride film (Si₃N₄ film). For example, the thickness of the middle layer insulating film 13 is about 30 to 300 nm, although it is not limited thereto. For example, the upper layer insulating film 14 is made of a silicon oxide film (SiO₂ film). For example, the thickness of the upper layer insulating film 14 is about 30 to 300 nm, although it is not limited thereto. Alternatively, the upper layer insulating film 14 may be omitted.

The lower layer insulating film 12, the middle layer insulating film 13, and the upper layer insulating film 14 are each provided with an opening (contact hole) for exposing a part of the upper surface of the semiconductor layer 11. For example, the diameters of openings of the lower layer insulating film 12, the middle layer insulating film 13, and the upper layer insulating film 14 are about 30 to 100 nm, but are not limited thereto. The openings of the lower layer insulating film 12, the middle layer insulating film 13, and the upper layer insulating film 14 are filled with an electrically conductive layer 18. The lower edge of the electrically conductive layer 18 is in contact with the upper surface of the semiconductor layer 11. For example, the electrically conductive layer 18 is made of a metal material such as copper (Cu), aluminum (Al), and tungsten (W). Although the illustration is omitted, wirings are connected to the upper edge of the electrically conductive layer 18. The electrically conductive layer 18 functions as a contact or a via to electrically connect the semiconductor layer 11 to wirings or the like. For example, the plane pattern of the electrically conductive layer 18 is rectangular, but even may be a circle or groove shape.

Between the middle layer insulating film 13 and the electrically conductive layer 18, an alteration layer (modified layer) 15 is formed so as to surround the lateral side surface of the electrically conductive layer 18. The inside lateral side surface (inner circumferential surface) of the alteration layer 15 is in contact with the lateral side surface of the electrically conductive layer 18. The thickness T1 in the circumferential direction (horizontal direction of FIG. 1) sandwiched between the middle layer insulating film 13 and the electrically conductive layer 18 of the alteration layer 15 becomes thinner toward the semiconductor layer 11. The outside lateral side surface (outer circumferential surface) in contact with the middle layer insulating film 13 of the alteration layer 15 has a stepped shape. FIG. 1 illustrates a case where the differences in level T2 of the stepped shape are substantially equal. In addition, FIG. 1 illustrates a case where the number of the steps of the stepped shape of the alteration layer 15 is six, but the number of the steps is not particularly limited, and even may be one step, or may be one to five steps, and may be seven or more steps.

The alteration layer 15 is constituted of domains in which the middle layer insulating film 13 is oxidized to alter (modify) the quality thereof. The alteration layer 15 is a layer containing oxygen and consists, for example, of silicon oxide (SiOₓ) such as silicon monoxide (SiO) or silicon dioxide (SiO₂), or silicon oxynitride (SiON). For example, the oxygen concentration in the alteration layer 15 may have a gradient from the inside toward the outside so that the side of the lateral side surface in contact with the electrically conductive layer 18 of the alteration layer 15 consists of SiOₓ and the side of the lateral side surface in contact with the middle layer insulating film 13 of the alteration layer 15 consists of SiON.

Here, the passivation characteristics of Si₃N₄ are higher than the passivation characteristics of SiON, and the passivation characteristics of SiON are higher than the passivation characteristics of SiOₓ. Therefore, the passivation characteristics of the middle layer insulating film 13 consisting of Si₃N₄ are higher than the passivation characteristics of the alteration layer 15 consisting of SiON or SiOₓ.

In addition, the dielectric constant (7.0) of Si₃N₄ is higher than the dielectric constant (4.2) of SiON or SiOₓ. Therefore, the dielectric constant of the middle layer insulating film 13 consisting of Si₃N₄ is higher than the dielectric constant of the alteration layer 15 consisting of SiON or SiOₓ.

In addition, the pressure tightness of SiOₓ is higher than pressure tightness of SiON, and the pressure tightness of SiON is higher than the pressure tightness of Si₃N₄. Therefore, the pressure tightness of the alteration layer 15 consisting of SiON or SiOₓ is higher than pressure tightness of the middle layer insulating film 13 consisting of Si₃N₄.

According to the semiconductor device according to the first embodiment, a lower dielectric constant can be achieved compared with a case where no alteration layer 15 is provided due to the oxygen-containing alteration layer 15 disposed between the middle layer insulating film 13 and the electrically conductive layer 18. Thus, the capacity can be reduced, and the speed of the device can be made higher. Furthermore, the pressure tightness can be enhanced, and the leak current can be reduced compared with a case where no alteration layer 15 is provided because the pressure tightness of the alteration layer 15 is higher than the pressure tightness of the middle layer insulating film 13.

Furthermore, since the shorter the distance to the semiconductor layer 11 is, the thinner the thickness T1 in the circumferential direction of the alteration layer 15 is, the passivation characteristics to the moisture and gas in the vicinity of the semiconductor layer 11 can be improved, and the deterioration of the device characteristics can be prevented. In addition, the oxidation of the semiconductor layer 11 of the part exposed to the contact hole can be suppressed, and the increase of the contact resistance can be suppressed.

<Etching Apparatus>

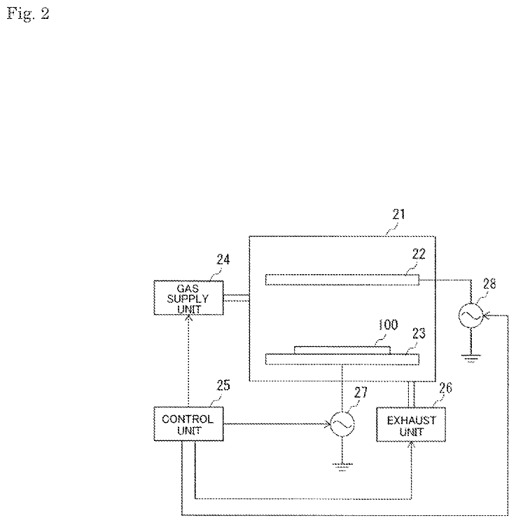

Next, a schematic configuration of an etching apparatus (plasma processing apparatus) according to the first embodiment of the present disclosure for conducting the etching method of the semiconductor device according to the first embodiment, which will be described later, is described. As shown in FIG. 2, the plasma processing device according to the first embodiment includes a processing container 21 for storing an object to be processed 100.

In the processing container 21, a lower part electrode 23 on which the object to be processed 100 is placed and an upper part electrode 22 disposed so as to face the lower part electrode 23. High frequency power sources 27 and 28 are connected to the lower part electrode 23 and the upper part electrode 22, respectively. The high frequency power source 27 produces high frequency electricity (high frequency voltage) to draw ions into the object to be processed 100. The high frequency power source 28 produces high frequency electricity for plasma generation.

A gas supply unit 24 and an exhaust unit 26 are connected to the processing container 21. The gas supply unit 24 supplies various kinds of gas, such as processing gas, selectively in the processing container 21 while regulating the flow rate. For example, the exhaust unit 26 is constituted of a vacuum pump, such as a turbomolecular pump, and depressurizes the processing container 21.

A control unit 25 is electrically connected to the gas supply unit 24, the exhaust unit 26, and the high frequency power sources 27 and 28. The control unit 25 controls the gas selection and the flow rate of the gas supply unit 24, the exhaust amount of the exhaust unit 26, the electricity supply amount from the high frequency power sources 27 and 28, and the like. Note that the plasma processing device according to the first embodiment illustrated in FIG. 2 is schematic, and actually, the plasma processing device further includes various components, the illustration of which is omitted.

<Etching Method>

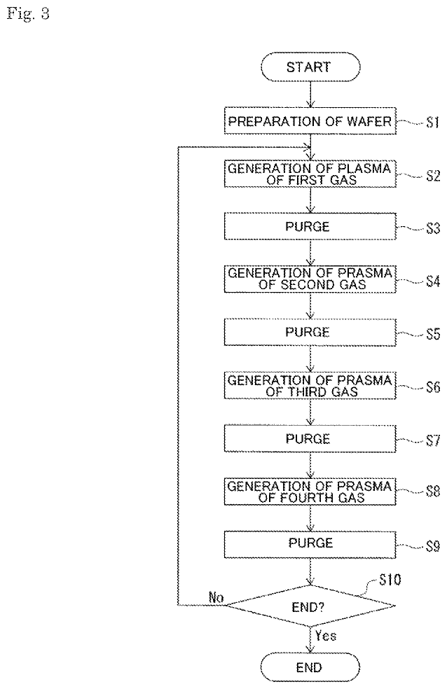

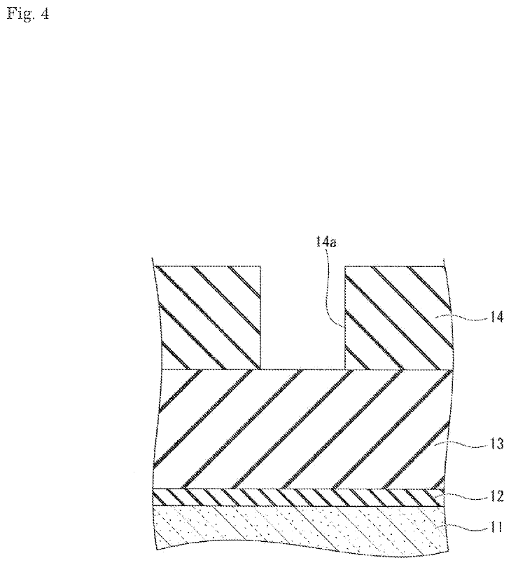

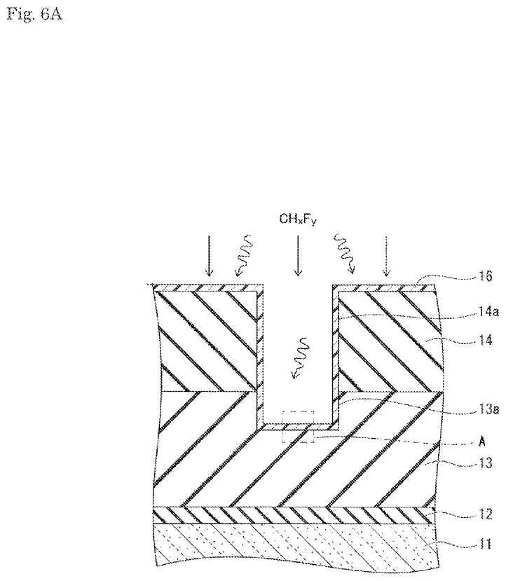

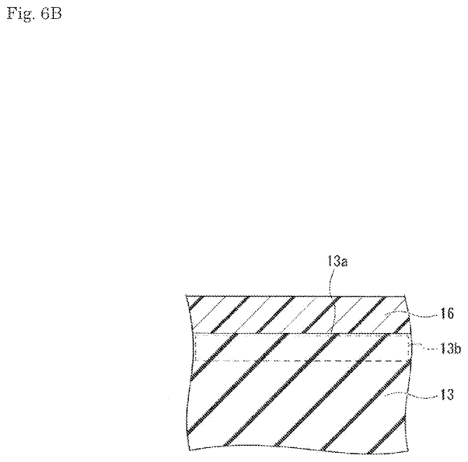

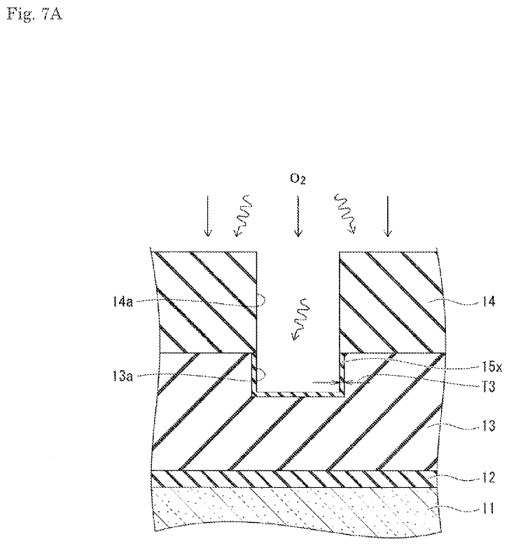

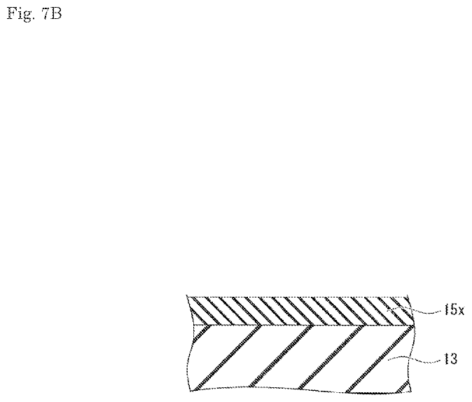

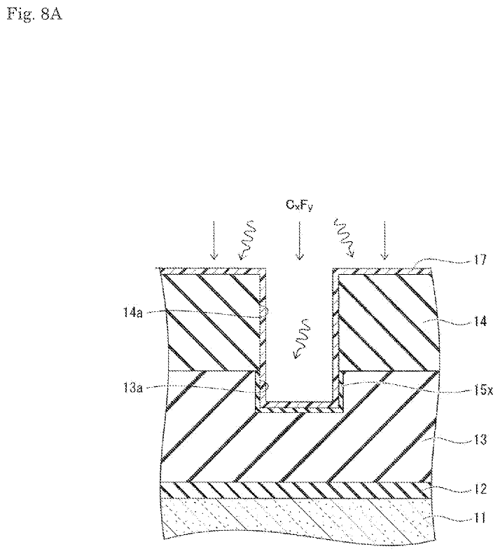

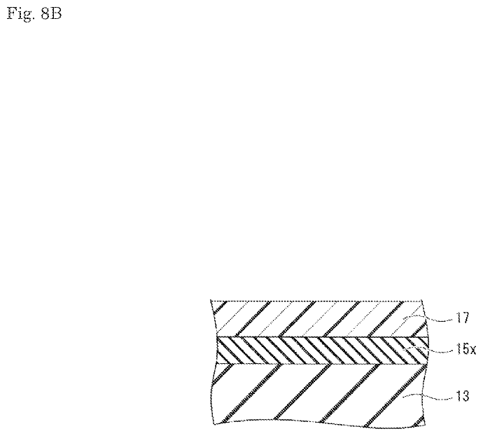

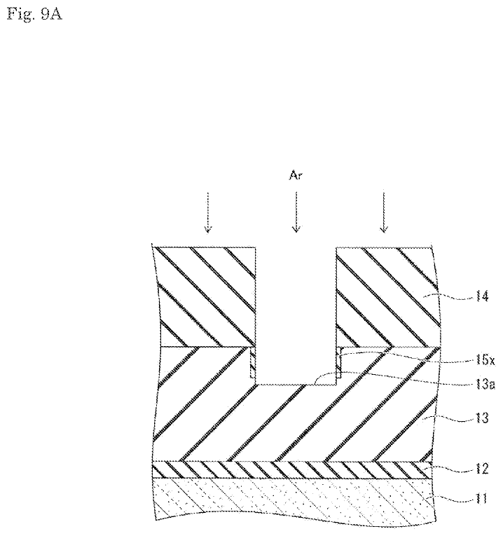

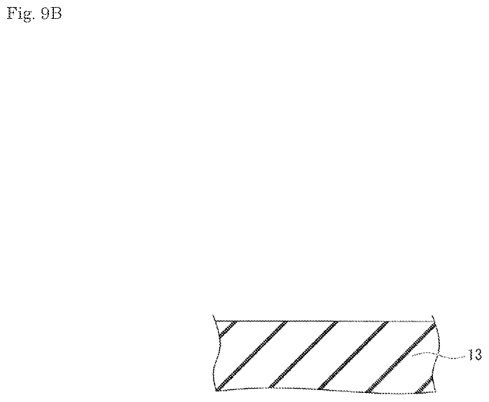

Next, with reference to the flow chart of FIG. 3 and the process cross-sectional views of FIGS. 4 to 10, the etching method of the semiconductor device according to the first embodiment is described. FIGS. 6A and 6B illustrate the same process, and an enlarged view of the part A, which is surrounded by dashed lines in FIG. 6A, is FIG. 6B. Also, the relationships between FIGS. 7A and 7B, between FIGS. 8A and 8B, and between FIGS. 9A and 9B are also the same as the relationship between FIGS. 6A and 6B.

In the step S1 of FIG. 3, an object to be processed (semiconductor wafer), which is a target of processing in the etching method of the semiconductor device according to the first embodiment, is prepared. As shown in FIG. 4, the semiconductor wafer includes a semiconductor layer 11, a lower layer insulating film 12 disposed on the semiconductor layer 11, a middle layer insulating film (a film to be etched) 13 disposed on the lower layer insulating film 12, and an upper layer insulating film 14 disposed on the middle layer insulating film 13. Alternatively, the lower layer insulating film 12 may not be formed. Using a photolithography technique and an etching technique, a part of the upper layer insulating film 14 is removed selectively, and opening 14a for exposing a part of the upper surface of the middle layer insulating film 13 is formed.

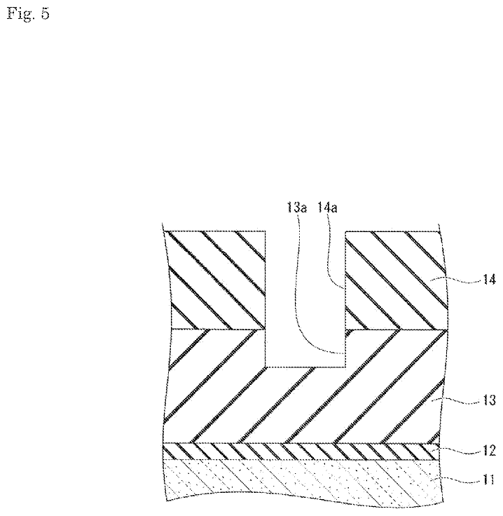

Next, the semiconductor wafer illustrated in FIG. 4 is placed on the lower part electrode 23 of the processing container 21 as an object to be processed 100, as illustrated in FIG. 2. Using the upper layer insulating film 14 as an etching mask, a part of the upper part of the middle layer insulating film 13 is selectively removed by normal dry etching such as reactive ion etchings (RIE). As a result, a recess part 13a with the predetermined depth is formed in the upper part of the middle layer insulating film 13, as illustrated in FIG. 5.

In the step S2 of FIG. 3, the first gas is supplied into the processing container 21 by the gas supply unit 24 illustrated in FIG. 2 to produce plasma of the first gas. For example, the first gas contains CHₓF_{y} gas containing carbon (C), fluorine (F), and hydrogen (H). Specific examples of the first gas include trifluoromethane (CHF₃) gas, difluoromethane (CH₂F₂) gas, and fluoromethane (CH₃F) gas. Besides the first gas, an inert gas consisting of noble gas, such as argon (Ar), or nitrogen (N₂) may be supplied to the processing container 21 and be diluted appropriately.

In an example of the process condition at the time of the plasma production of the first gas in the step S2, the pressure in the processing container 21 is set to about 20 to 30 mTorr, the power of the upper part electrode 22 is set to about 400 to 600 W, the high frequency voltage is set to 0 V, the flow rate of the first gas is set to about 5 to 15 sccm, the flow rate of Ar gas is set to about 400 to 600 sccm, and the processing time is set to about 5 to 20 seconds.

As illustrated in FIGS. 6A and 6B, ions (illustrated with straight arrows) and radicals (illustrated with wavy arrows) included in the plasma of the first gas deposits the first polymerization film 16 on the upper surface of the upper layer insulating film 14 and the lateral side surface of the opening 14a, and on the lateral side surface and the bottom surface of the recess part 13a of the middle layer insulating film 13. The first polymerization film 16 is attracted and adhered to the surface of the middle layer insulating film 13 positioned at the recess part 13a of the middle layer insulating film 13. The first polymerization film 16 consists, for example, of polymers containing carbon (C), fluorine (F), and hydrogen (H). The first polymerization film 16 is constituted, for example, of hydrofluorocarbons (HFC).

In the step S3 of FIG. 3, the first gas supplied in step S2 is exhausted by purging the inside of the processing container 21 by the exhaust unit 26 illustrated in FIG. 2. For example, the processing container 21 may be vacuumed, or purge gas such as Ar gas may be supplied into the processing container 21.

In the step S4 of FIG. 3, the second gas is supplied into the processing container 21 by the gas supply unit 24 illustrated in FIG. 2 to produce plasma of the second gas. The second gas is gas containing oxygen (O). Specific examples of the second gas include oxygen (O₂) gas, carbon monoxide (CO) gas, carbon dioxide (CO₂) gas, nitric oxide (NO) gas, nitrogen dioxide (NO₂) gas, and the like. Besides the second gas, an inert gas consisting of noble gas, such as argon (Ar), and nitrogen (N₂) may be supplied and diluted appropriately.

In an example of the process condition at the time of the plasma production of the second gas in the step S4, the pressure in the processing container 21 is set to about 20 to 30 mTorr, the power of the upper part electrode 22 is set to about 300 to 500 W, the high frequency voltage is set to 0 V, the flow rate of the second gas is set to about 400 to 600 sccm, and the processing time is set to about 20 to 40 seconds.

Due to oxygen ions and radicals included in the plasma of the second gas, the first polymerization film 16 illustrated in FIGS. 6A and 6B are removed, as illustrated in FIGS. 7A and 7B. At this time, the upper part (outer layer part) 13b (illustrated with dashed lines) of the middle layer insulating film 13, to which the first polymerization film 16 is attracted and adhered, as illustrated in FIG. 6B, detaches and is removed. Furthermore, as illustrated in FIGS. 7A and 7B, the surface of the middle layer insulating film 13 is oxidized (modified) to form the alteration layer (modified layer) 15x containing oxygen.

The thicknesses T3 of the alteration layer 15x are at the same level in the lateral side surface and the bottom surface of the recess part 13a of the middle layer insulating film 13. For example, the thickness T3 of the alteration layer 15x is about 3 nm to 10 nm and can be appropriately set by adjusting the plasma energy (high frequency electricity) of the second gas. The higher the plasma energy of the second gas is made, the thicker the thickness T3 of the alteration layer 15x becomes, and the higher the oxygen concentration in the alteration layer 15x also becomes. Meanwhile, the upper layer insulating film 14 does not deteriorate like the middle layer insulating film 13 because the upper layer insulating film 14 originally includes oxygen.

In the step S5 of FIG. 3, the second gas supplied into the step S4 is exhausted by purging the inside of the processing container 21 by the exhaust unit 26 illustrated in FIG. 2. For example, the processing container 21 may be vacuumed, or purge gas such as Ar gas may be supplied into the processing container 21.

In the step S6 of FIG. 3, the third gas is supplied into the processing container 21 by the gas supply unit 24 illustrated in FIG. 2 to produce plasma of the third gas. For example, the third gas is constituted of fluorocarbons (CₓF_{y})-based gas containing carbon and fluorine. Specific examples of the third gas include carbon tetrafluoride (CF₄) gas, perfluorocyclobutane (C₄F₈) gas, hexafluoro-1,3-butadiene (C₄F₆) gas, octafluorocyclopentene (C₅F₈) gas. Besides the third gas, an inert gas consisting of noble gas, such as argon (Ar), and nitrogen (N₂) may be supplied to the processing container 21 and be diluted appropriately.

In an example of the process condition at the time of the plasma production of the third gas in the step S6, the pressure in the processing container 21 is set to about 20 to 30 mTorr, the power of the upper part electrode 22 is set to about 400 to 600 W, the high frequency voltage is set to 0 V, the flow rate of the CF-based gas, which is a third gas, is set to about 5 to 20 sccm, the flow rate of the Ar gas is set to about 400 to 600 sccm, and the processing time is set to about 5 to 15 seconds.

As illustrated in FIGS. 8A and 8B, ions and radicals included in the plasma of the third gas attract and adhere a second polymerization film 17 to the surface of the alteration layer 15. The second polymerization film 17 consists of CF polymers containing carbon (C) and fluorine (F).

In the step S7 of FIG. 3, the third gas supplied into the step S6 is exhausted by purging the inside of the processing container 21 by the exhaust unit 26 illustrated in FIG. 2. For example, the processing container 21 may be vacuumed, or purge gas such as Ar gas may be supplied into the processing container 21.

In the step S8 of FIG. 3, the fourth gas is supplied into the processing container 21 by the gas supply unit 24 illustrated in FIG. 2 to produce plasma of the fourth gas. The fourth gas is gas containing noble gas. Specific examples of the fourth gas include helium (He), neon (Ne), argon (Ar), krypton (Kr), xenon (Xe), and the like.

In an example of the process condition at the time of the plasma production of the fourth gas in the step S8, the pressure in the processing container 21 is set to about 20 to 30 mTorr, the power of the upper part electrode 22 is set to about 300 to 400 W, the high frequency voltage is set to 70 V, the flow rate of Ar gas, which is a fourth gas, is set to about 400 to 500 sccm, and the processing time is set to about 20 to 40 seconds.

As illustrated in FIGS. 9A and 9B, due to noble gas ions included in the plasma of the fourth gas, the alteration layer 15x detaches and is removed together with the second polymerization film 17. At this time, the alteration layer 15x of the bottom surface of the recess part 13a of the middle layer insulating film 13 is substantially fully removed, and the middle layer insulating film 13 is thereby removed. Meanwhile, as illustrated in FIG. 9A, the lateral side surface of the recess part 13a of the middle layer insulating film 13 is removed thinly because the Ar ion penetration is shallower compared with the bottom surface of the recess part 13a. Therefore, the alteration layer 15x of the deep part of the lateral side surface of the recess part 13a remains.

In the step S9 of FIG. 3, the fourth gas supplied into the step S8 is exhausted by purging the inside of the processing container 21 by the exhaust unit 26 illustrated in FIG. 2. For example, the processing container 21 may be vacuumed, or purge gas such as Ar gas may be supplied into the processing container 21.

In the step S10 of FIG. 3, whether the predetermined number of times of the cycles, wherein each cycle includes the procedures of the steps S2 to S9, are repeated or not is determined. The predetermined number of times is settable in advance as the number of times to achieve the predetermined etching amount. The predetermined number of times is one, and the procedures of the steps S2 to S9 do not have to be repeated. If the cycles are not repeated the predetermined number of times, the procedure returns to the steps S2, and cycles of the steps S2 to S9 are repeated. In each cycle, the process condition may be identical among the cycles, and may be different between cycles.

The depth of the recess part 13a of the middle layer insulating film 13 is deepened by repeating cycles including the steps S2 to S9 of FIG. 3 plural numbers of times. In addition, the thickness of the alteration layer 15x of the lateral side surface of the recess part 13a of the middle layer insulating film 13 becomes thick every plasma production of the second gas of the step S4 in each cycle. Therefore, one step of the steps of the alteration layer 15x is formed every cycle.

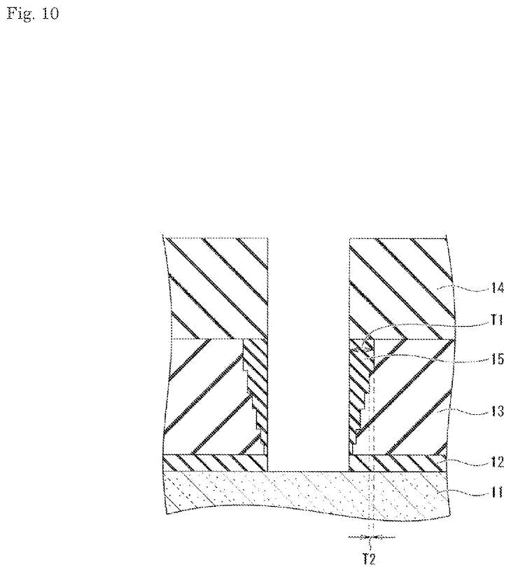

If the cycles of the steps S2 to S9 were repeated the predetermined number of times in the step S10 of FIG. 3, polymers, natural oxide films, and the like are removed using dilute hydrofluoric acid (DHF), and an etching process is completed. As a result, as illustrated in FIG. 10, the middle layer insulating film 13 and the lower layer insulating film 12 are removed, and an opening (contact hole) is formed in the middle layer insulating film 13 and the lower layer insulating film 12, and a part of the upper surface of the semiconductor layer 11 is exposed. The thickness T1 in the circumferential direction of the alteration layer 15 becomes thinner toward the semiconductor layer 11, and the outer circumference surface of the alteration layer 15 becomes a stepped shape. The differences in level T2 of the stepped shape of the outer circumference surface of the alteration layer 15 can be formed substantially evenly by making the plasma energy of the second gas of the step S4 identical in each cycle of the steps S2 to S9 of FIG. 3.

After that, the semiconductor device illustrated in FIG. 1 is produced by filling the electrically conductive layer 18 in the opening (contact hole) of the lower layer insulating film 12, the middle layer insulating film 13, and the upper layer insulating film 14 using a chemical vapor deposition (CVD) method. The electrically conductive layer 18 may be filled in the opening (contact hole) of the lower layer insulating film 12 and the middle layer insulating film 13 after the upper layer insulating film 14 is removed.

According to the etching method of the semiconductor device according to the first embodiment, selecting the middle layer insulating film 13 consisting of Si₃N₄ as an object to be etched, the middle layer insulating film 13 can be removed every atomic layer by atomic layer etching (ALE) that repeats at least four times plasma productions and purges of the procedures of the steps S2 to S9. The high selection ratio with the semiconductor layer 11 is thereby enabled, and low damage processing is enabled in this way.

The left side of the graph in FIG. 10 shows a result of the argon (Ar) ion penetration simulation when the power of the upper part electrode 22 was set to 30 W (18 eV), and processing was conducted for 60 seconds using ALE. The profile of the solid line of FIG. 10 shows the distribution of Ar ions and shows the profile obtained by converting the distribution into consecutive values in a dashed line. The right side of the graph in FIG. 10 represents composition in the depth direction from the Si surface measured using an ellipsometer. FIG. 10 shows that the penetrated depth of Ar ions into Si is 5 nm or less, the degree of the recess amount of Si, and that the thickness of the alteration layer 15 becomes 5 nm or less.

### First Comparative Example

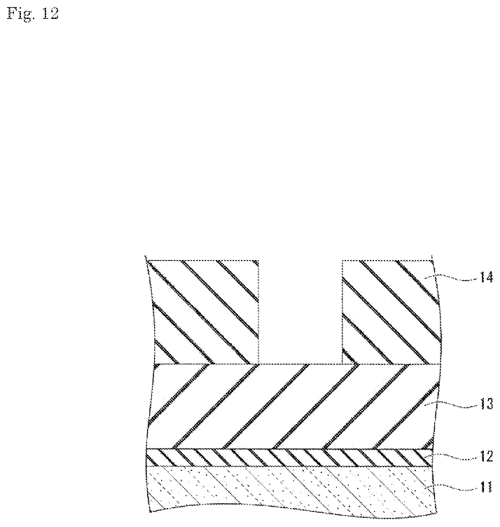

Next, the etching method according to a first comparative example is described. In the etching method according to a first comparative example, as illustrated in FIG. 12, a semiconductor wafer including a semiconductor layer 11, a lower layer insulating film 12 disposed on the semiconductor layer 11, a middle layer insulating film 13 disposed on the lower layer insulating film 12, and an upper layer insulating film 14 disposed on the middle layer insulating film 13 is prepared. Using a photolithography technique and an etching technique, a part of the upper layer insulating film 14 is removed selectively, and an opening is formed.

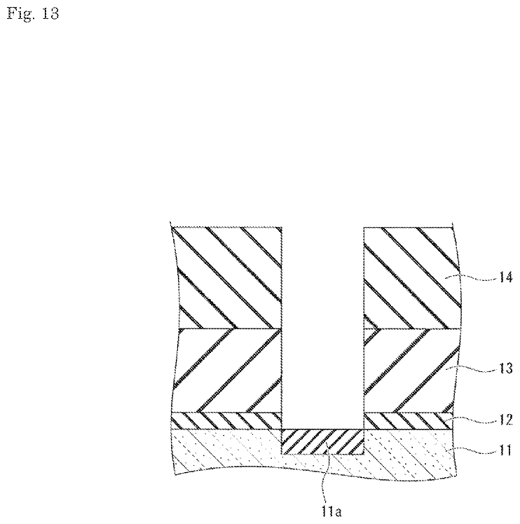

Next, as illustrated in FIG. 13, using the upper layer insulating film 14 as an etching mask, the middle layer insulating film 13 and the lower layer insulating film 12 are removed by reactive ion etchings (RIE). At this time, the upper part of the semiconductor layer 11 is oxidized, and an oxidation layer 11a is formed by over-etching.

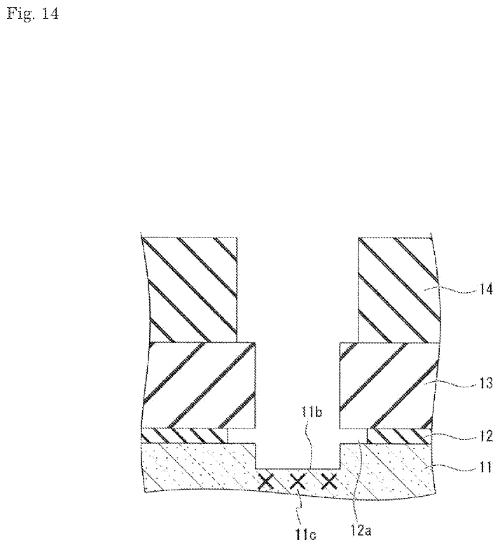

Next, by performing DHF processing, as illustrated in FIG. 14, the oxidation layer 11a of the upper part of the semiconductor layer 11 is removed to form a recess part (recess) lib, and furthermore, residual defects 11c of the Si occurs in the bottom of the recess part lib. Dark current increases due to the formation of this recess part 11b and the occurrence of the residual defects 11c. In addition, there is a concern about yield deterioration and metal filling failure because a slit 12a occurs in the lower layer insulating film 12 in the lateral direction.

In contrast, the etching method of the semiconductor device according to the first embodiment can suppress the formation of recess parts in the semiconductor layer 11 due to over-etching, as illustrated in FIG. 10, or, even if recess parts are formed, can make the depth of the recess part of the semiconductor layer 11 shallower (for example, about 5 nm or less) than the recess part 11b of the first comparative example. Furthermore, a dark current can be reduced because the residual defects at the bottom of the recess part of the semiconductor layer 11 can also be suppressed or decreased. Furthermore, as illustrated in FIG. 10, the formation of slits in the lateral direction of the lower layer insulating film 12 can be suppressed, and therefore, the yield can be increased, and the metal filling failure can be suppressed.

### Second Comparative Example

Next, an etching method according to the second comparative example is described. In the etching method according to the second comparative example, as illustrated in FIG. 12, a semiconductor wafer including a semiconductor layer 11, a lower layer insulating film 12 disposed on the semiconductor layer 11, a middle layer insulating film 13 disposed on the lower layer insulating film 12, and an upper layer insulating film 14 disposed on the middle layer insulating film 13 is prepared, as with the first comparative example. Using a photolithography technique and an etching technique, a part of the upper layer insulating film 14 is removed selectively, and an opening is formed.

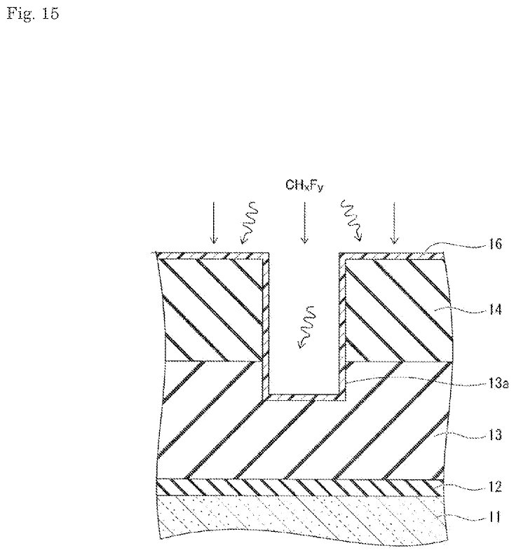

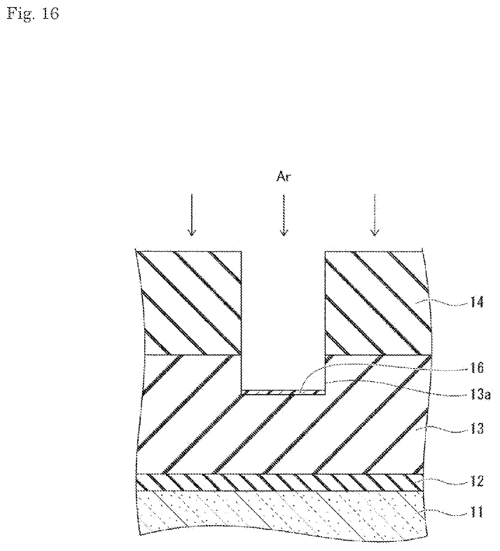

Next, a recess part 13a with the predetermined depth is formed in the middle layer insulating film 13. Then, a cycle including a procedure to produce plasma of the CHₓF_{y}-based gas to attract and adhere the first polymerization film 16 as illustrated in FIG. 15 and a procedure to produce plasma of Ar gas to remove the middle layer insulating film 13 as illustrated in FIG. 16 are repeated. At this time, a part of the first polymerization film 16 may remain when the plasma of Ar gas is produced in some cases, as illustrated in FIG. 16. Therefore, the film thickness of the first polymerization film 16 may be thick, and removal of the middle layer insulating film 13 may become difficult in some cases if the procedures illustrated in FIGS. 15 and 16 are repeated.

In contrast, the etching method of the semiconductor device according to the first embodiment can easily remove the middle layer insulating film 13 without remaining the first polymerization film 16 by repeating the procedures of the steps S2 to S9 illustrated in FIG. 3.

### Second Embodiment

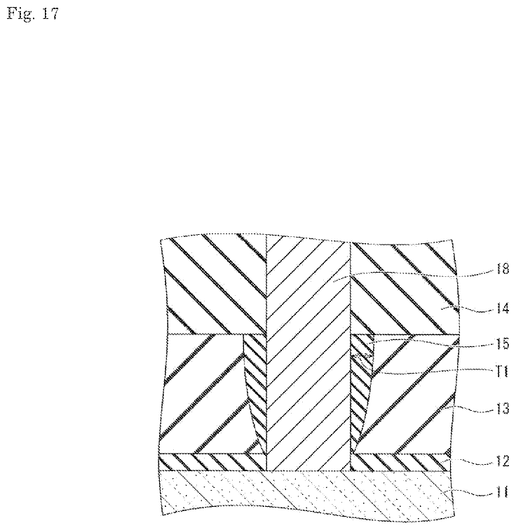

The semiconductor device according to the second embodiment is different from the semiconductor device according to the first embodiment illustrated in FIG. 1 in that the outer circumferential surface of the alteration layer 15 is substantially curved surface (tapered shape) as illustrated in FIG. 17. Since the difference in level of the stepped shape of the outer circumferential surface of the alteration layer 15 is shallower and is formed more minutely compared with the semiconductor device according to the first embodiment illustrated in FIG. 1, steps are connected continually and can be considered a substantially curved surface. The thickness T1 in the circumferential direction of the alteration layer 15 becomes thinner toward the semiconductor layer 11. Overlapped descriptions are omitted about other constitutions of the semiconductor device according to the second embodiment because such other constitutions are similar to the semiconductor device according to the first embodiment illustrated in FIG. 1.

The etching method of the semiconductor device according to the second embodiment is similar to the etching method of the semiconductor device according to the first embodiment, and the plasma energy of the second gas should be reduced when the plasma of the second gas of the step S4 illustrated in FIG. 3 is produced.

### Third Embodiment

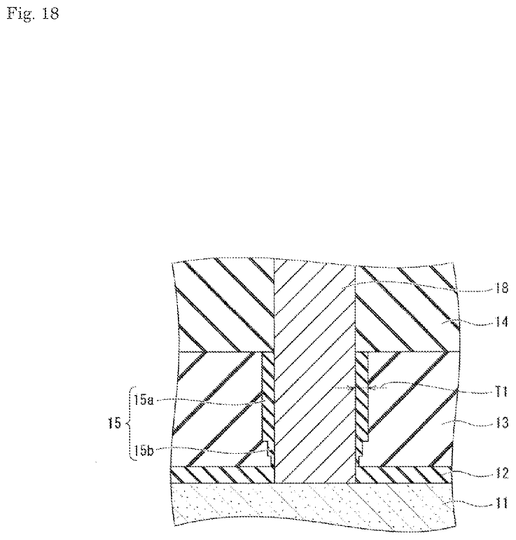

The semiconductor device according to the third embodiment is different from the semiconductor device according to the first embodiment illustrated in FIG. 1 in the shape of the alteration layer 15, as illustrated in FIG. 18. The outer circumferential surface of the upper part 15a of the alteration layer 15 is substantially perpendicular, and the thickness T1 in the circumferential direction of the upper part 15a of the alteration layer 15 is substantially constant. The outer circumferential surface of the lower part 15b of the alteration layer 15 is a stepped shape, and the thickness T1 in the circumferential direction of the lower part 15b of the alteration layer 15 becomes thinner toward the semiconductor layer 11. Overlapped descriptions are omitted about other constitutions of the semiconductor device according to the third embodiment because such other constitutions are similar to the semiconductor device according to the first embodiment illustrated in FIG. 1.

In the etching method of the semiconductor device according to the third embodiment, the middle layer insulating film 13 of the bottom of the recess part 13a is removed by the predetermined depth by dry etching such as RIE after the formation of the recess part 13a on the middle layer insulating film 13, as illustrated in FIG. 5, and before the production of the plasma of the second gas of the step S2, which is illustrated in FIG. 3, in the etching method of the semiconductor device according to the first embodiment. After that, the procedures of steps S2 to S9 illustrated in FIG. 3 are repeated. As a result, the outer circumferential surface of the upper part 15a of the alteration layer 15, corresponding to the position where the middle layer insulating film 13 was removed by dry etching such as RIE, becomes substantially perpendicular, as illustrated in FIG. 18. Meanwhile, the outer circumferential surface of the lower part 15b of the alteration layer 15, corresponding to the position where the middle layer insulating film 13 was removed by repeating the procedures of the steps S2 to S9 illustrated in FIG. 3, becomes a stepped shape.

According to the etching method of the semiconductor device according to the third embodiment, the repetition number of times of the procedures of the steps S2 to S9 can be reduced by using normal dry etching in the former half of the etching process of the middle layer insulating film 13. Meanwhile, the formation of the recess part of the semiconductor layer 11 can be suppressed or the depth of the recess can be reduced by repeating the procedures of the steps S2 to S9 in the latter half of the etching process of the middle layer insulating film 13.

### Fourth Embodiment

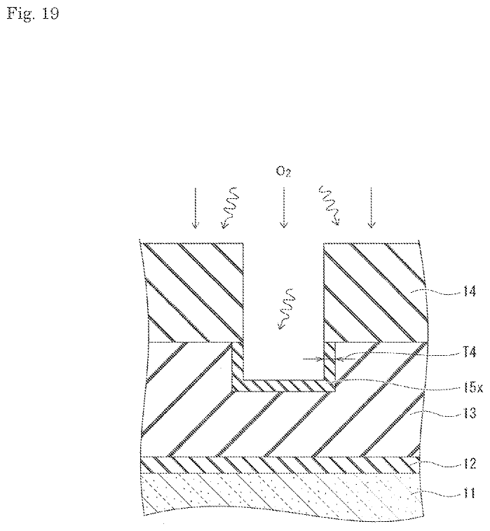

In the following fourth to sixth embodiments, examples where the plasma energy of the second gas is increased at the time when the plasma of the second gas in the step S4 illustrated in FIG. 3 is produced, compared with the etching method of the semiconductor device according to the first embodiment. For example, when the plasma energy of the second gas in the step S4 illustrated in FIG. 3 is increased, the thickness T4 in the circumferential direction of the alteration layer 15x becomes thicker, as illustrated in FIG. 19, compared with the thickness T3 in the circumferential direction of the alteration layer 15x illustrated in FIG. 7A.

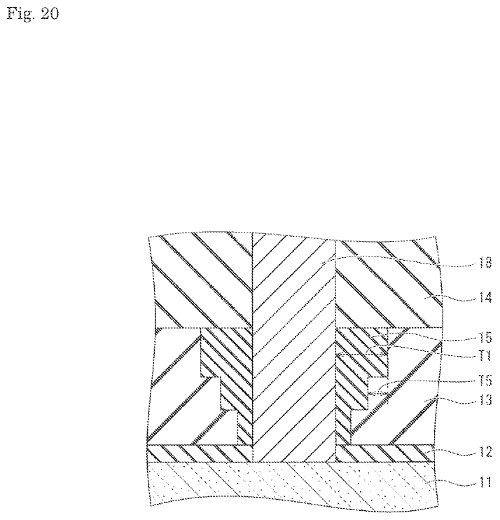

The semiconductor device according to the fourth embodiment shares the same feature with the semiconductor device according to the first embodiment illustrated in FIG. 1 in that, as illustrated in FIG. 20, the circumferential outer surface of the alteration layer 15 has a stepped shape, and the thickness T1 in the circumferential direction of the alteration layer 15 becomes thinner toward the semiconductor layer 11. However, the semiconductor device according to the fourth embodiment has a difference in level T5 of the stepped shape of the outer circumferential surface of the alteration layer 15 larger than the difference in level T2 of the semiconductor device according to the first embodiment illustrated in FIG. 1. Overlapped descriptions are omitted about other constitutions of the semiconductor device according to the fourth embodiment because such other constitutions are similar to the semiconductor device according to the first embodiment illustrated in FIG. 1.

The etching method of the semiconductor device according to the fourth embodiment should be performed so that the plasma energy of the second gas is increased in the step S4, as illustrated in FIG. 19, when the procedures of the steps S2 to S9 illustrated in FIG. 3 are repeated in the etching method of the semiconductor device according to the first embodiment.

According to the etching method of the semiconductor device according to the fourth embodiment, the etching amount in one cycle of the steps S2 to S9 illustrated in FIG. 3 can be increased, and the repetition number of times of the procedures of the steps S2 to S9 illustrated in FIG. 3 can be decreased.

### Fifth Embodiment

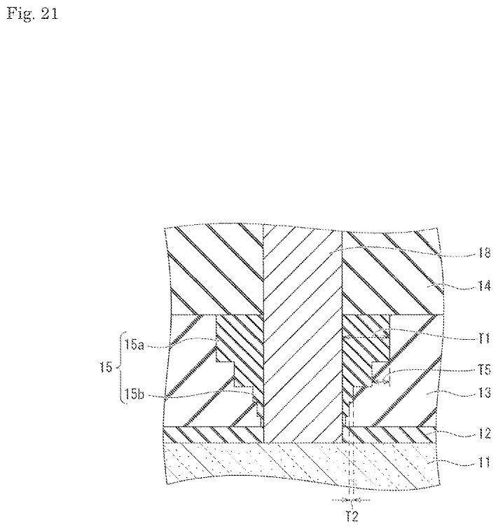

The semiconductor device according to the fifth embodiment is different from the semiconductor device according to the first embodiment illustrated in FIG. 1 in the shape of the upper part 15a of the alteration layer 15, as illustrated in FIG. 21. The outer circumferential surface of the upper part 15a of the alteration layer 15 is a stepped shape, and the thickness T5 of a step of the stepped shape is substantially constant. Meanwhile, the outer circumferential surface of the lower part 15b of the alteration layer 15 is also a stepped shape, but the thickness T2 of a step of the stepped shape is thinner than the thickness T5 of a step of the upper part 15a of the alteration layer 15. Overlapped descriptions are omitted about other constitutions of the semiconductor device according to the fifth embodiment because such other constitutions are similar to the semiconductor device according to the first embodiment illustrated in FIG. 1.

The etching method of the semiconductor device according to the fifth embodiment should be performed so that, in the etching method of the semiconductor device according to the first embodiment, the plasma energy of the second gas of the step S4 is made relatively larger in the former half of the plural number of cycles in the procedures of the step S2 to S9 illustrated in FIG. 3 in the etching method of the semiconductor device according to the first embodiment. After that, in the cycle of the latter half of the plural number of cycles in the procedures of the steps S2 to S9 illustrated in FIG. 3, the plasma energy of the second gas of the step S4 is made relatively smaller.

According to the etching method of the semiconductor device according to the fifth embodiment, the etching amount in one cycle can be increased in the former half of the plural number of cycles, and the repetition number of times of the cycles can be decreased. Meanwhile, the formation of the recess part of the semiconductor layer 11 can be suppressed or the depth of the recess part can be reduced by decreasing the etching amount in one cycle and enhancing the etching accuracy in the latter half of the plural number of cycles.

### Sixth Embodiment

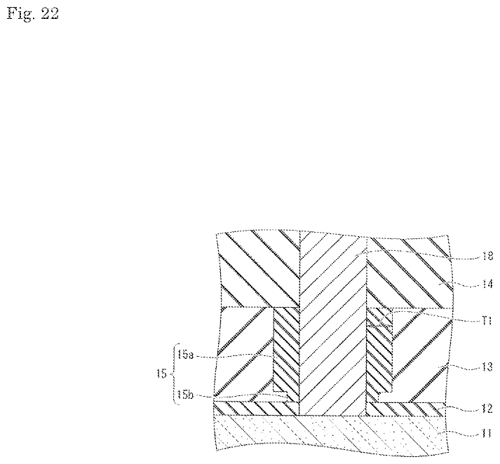

The semiconductor device according to the sixth embodiment is different from the semiconductor device according to the first embodiment illustrated in FIG. 1 in the shapes of the upper part 15a and the lower part 15b of the alteration layer 15, as illustrated in FIG. 22. The outer circumferential surface of the upper part 15a of the alteration layer 15 is substantially perpendicular, and the thickness T1 in the circumferential direction of the upper part 15a of the alteration layer 15 is substantially constant. The outer circumferential surface of the lower part 15b of the alteration layer 15 is a stepped shape. Note that although the number of steps of the stepped shape of the lower part 15b of the alteration layer 15 is one in FIG. 22, the number may be plural. Overlapped descriptions are omitted about other constitutions of the semiconductor device according to the sixth embodiment because such other constitutions are similar to the semiconductor device according to the first embodiment illustrated in FIG. 1.

In the etching method of the semiconductor device according to the sixth embodiment, the recess part 13a is formed on the middle layer insulating film 13 as illustrated in FIG. 5, and thereafter, the middle layer insulating film 13 of the bottom of the recess part 13a is removed by the predetermined depth by dry etching such as RIE, in the etching method of the semiconductor device according to the first embodiment. After that, the procedures of the steps S2 to S9 illustrated in FIG. 3 are repeated, provided that the plasma energy of the second gas of the step S4 is made relatively larger than that of in the etching method of the semiconductor device according to the first embodiment. As a result, the outer circumferential surface of the upper part 15a of the alteration layer 15, corresponding to the position where the middle layer insulating film 13 was removed by dry etching such as RIE, becomes substantially perpendicular, as illustrated in FIG. 22. Meanwhile, the outer circumferential surface of the lower part 15b of the alteration layer 15, corresponding to the position where the middle layer insulating film 13 was removed by repeating the procedures of the steps S2 to S9 illustrated in FIG. 3, becomes a stepped shape.

According to the etching method of the semiconductor device according to the sixth embodiment, the repetition number of times of the procedures of the steps S2 to S9 can be reduced by using normal dry etching in the former half of the etching process of the middle layer insulating film 13. Meanwhile, the formation of the recess part of the semiconductor layer 11 can be suppressed or the depth of the recess part can be reduced by repeating the procedures of the steps S2 to S9 in the latter half of the etching process of the middle layer insulating film 13.

### Seventh Embodiment

In the seventh embodiment, solid-state image pickup devices and electronic devices, to which the semiconductor devices of the first to sixth embodiments can be applied, are listed as examples.

<Electronic Device>

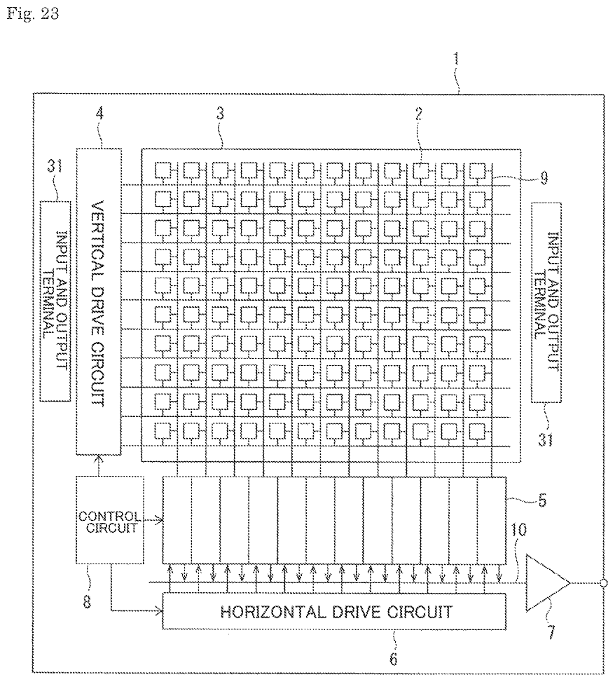

As an example of a solid-state image pickup device according to the seventh embodiment, a CMOS(Complementary Metal Oxide Semiconductor) image sensor is described. The solid-state image pickup device according to the seventh embodiment includes pixel domains (image pickup domain) 3, in which pixels 2 are arranged in a matrix, and peripheral circuits (4, 5, 6, 7, and 8) that processes pixel signals outputted from the pixel domain 3 as illustrated in FIG. 23.

The pixel 2 generally has a photoelectric conversion domain constituted of a photodiode electrically converting incident light and a plurality of pixel transistors to read the signal electric charge that occurred by the photoelectric conversion in the photoelectric conversion domain. For example, the plurality of pixel transistors may be constituted of three transistors: a transfer transistor, a reset transistor, and an amplifier transistor. Alternatively, the plurality of pixel transistors may be constituted of four transistors further including a selection transistor.

The peripheral circuits (4, 5, 6, 7, and 8) includes a vertical drive circuit 4, a column signal processing circuit 5, a horizontal drive circuit 6, an output circuit 7, and a control circuit 8. The control circuit 8 receives an input clock and data to instruct a movement mode and the like, and outputs data such as the inside information of the solid-state image pickup device. For example, the control circuit 8 produces a clock signal or a control signal as a reference for operations of the vertical drive circuit 4, the column signal processing circuit 5, the horizontal drive circuit 6, and the like on the basis of a vertical synchronization signal, a horizontal synchronization signal, and a master clock. The control circuit 8 outputs the generated clock signal or control signal to the vertical drive circuit 4, the column signal processing circuit 5, the horizontal drive circuit 6, and the like.

For example, the vertical drive circuit 4 is constituted of a shift register. The vertical drive circuit 4 selects a pixel driving wiring, supplies a pulse for driving the pixels 2 to the selected pixel driving wiring, and drives the pixels 2 in units of rows. For example, the vertical drive circuit 4 sequentially performs selection scanning on the pixels 2 in the pixel domain 3 in the vertical direction in units of rows, and supplies a pixel signal based on signal charges produced in accordance with the amount of light received in, for example, the photodiode that serves as a photoelectric conversion domain of each of the pixels 2 to the column signal processing circuit 5 through the vertical signal line 9.

The column signal processing circuit 5 is located, for example, in every row of the pixel 2. The column signal processing circuit 5 performs signal processing, such as noise reduction, of signals outputted from the pixel 2 for one row every pixel column. For example, the column signal processing circuit 5 performs signal processing such as CDS, signal amplification, AD conversion, and the like for removing fixed pattern noise unique to the pixels 2. A horizontal selection switch (not shown) is connected and provided between the output end of the column signal processing circuit 5 and the horizontal signal line 10.

For example, the horizontal drive circuit 6 is constituted of a shift register. The horizontal drive circuit 6 sequentially outputs a horizontal scanning pulse and thus selects each of the column signal processing circuits 5 in order, and outputs a pixel signal from each of the column signal processing circuits 5 to the horizontal signal line 10.

The output circuit 7 performs signal processing on signals sequentially supplied through the horizontal signal line 10 from each of the column signal processing circuits 5 and outputs the pixel signals. For example, the output circuit 7 may only perform buffering, or may perform black level adjustment, column variation correction, various types of digital signal processing, and the like. The input and output terminal 31 exchanges signals with the outside.

In FIG. 23, the pixel domain 3 and the peripheral circuits (4, 5, 6, 7, and 8) of the solid-state image pickup device according to the seventh embodiment are formed on one substrate 1, but may be formed in a laminated structure in which a plurality of substrates are laminated. For example, the solid-state image pickup device according to the seventh embodiment may be constituted of the first and second substrates, and a photoelectric conversion domain and a pixel transistor may be disposed on the first substrate and peripheral circuits (3, 4, 5, 6, and 7), and the like may be disposed on the second substrate. Alternatively, a configuration, wherein part of photoelectric conversion domains and pixel transistors is disposed on the first substrate and part of the rest of the pixel transistor and the peripheral circuits (3, 4, 5, 6, and 7) and the like is disposed on the second substrate, may be adopted.

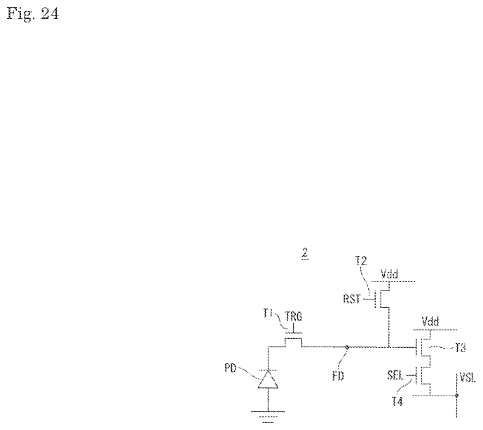

FIG. 24 illustrates an example of an equivalent circuit of a pixel 2 of the solid-state image pickup device according to the seventh embodiment. The anode of the photodiode PD, which is a photoelectric conversion domain of the pixel 2, is grounded, and the source of the transfer transistor T1, which is an active element, is connected to the cathode of the photodiode PD. A floating diffusion domain FD is connected to the drain of the transfer transistor T1. The floating diffusion domain FD is connected to the source of the reset transistor T2, which is an active element, and the gate of the amplification transistor T3, which is an active element. The source of the amplification transistor T3 is connected to the drain of a selection transistor T4, which is an active element, and the drain of the amplification transistor T3 is connected to a power source Vdd. The source of the selection transistor T4 is connected to a vertical signal line VSL. The drain of the reset transistor T2 is connected to a power source Vdd.

During the operation of the solid-state image pickup device according to the seventh embodiment, a control electric potential TRG is applied to the transfer transistor T1, and a signal electric charge produced in the photodiode PD is transferred to a floating diffusion domain FD. A signal electric charge transferred to the floating diffusion domain FD is read out and is applied to the gate of the amplification transistor T3. A selection signal SEL of the horizontal line is given from a vertical shift register to the gate of the selection transistor T4. Choice transistor T4 is conducted by making the selection signal SEL a high (H) level, and an electric current corresponding to the electric potential of the floating diffusion domain FD amplified in the amplification transistor T3 flows into the vertical signal line VSL. In addition, the reset transistor T2 is conducted by making a reset signal RST applied to the gate of the reset transistor T2 a high (H) level and resets a signal electric charge accumulated in the floating diffusion domain FD.

For example, a semiconductor device according to the first to sixth embodiment may be a semiconductor device including a semiconductor layer (diffusion layer) connected to an electrically conductive layer (contact) filled in the contact hole, such as the photodiode PD, the transfer transistor T1, the reset transistor T2, the amplification transistor T3, and the selection transistor T4, which are illustrated in FIG. 24.

<Electronic Device>

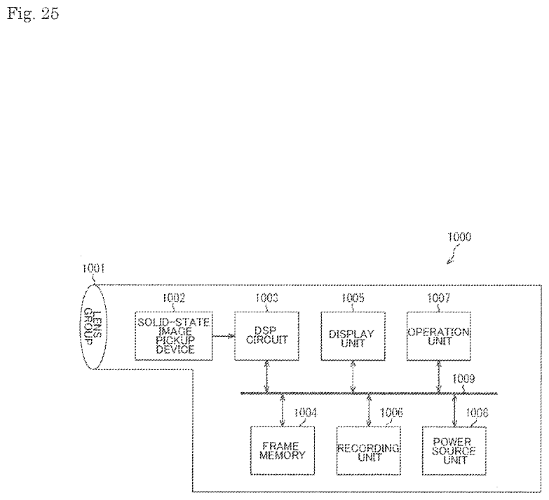

FIG. 25 is a block diagram illustrating a configuration example of an image pickup device as an electronic device to which the present disclosure is applied. The image pickup device 1000 of FIG. 25 is a video camera or a digital still camera, and the like. The image pickup device 1000 includes a lens group 1001, a solid-state image pickup device 1002, a DSP circuit 1003, a frame memory 1004, a display unit 1005, a recording unit 1006, an operation unit 1007, and a power source unit 1008. The DSP circuit 1003, the frame memory 1004, the display unit 1005, the recording unit 1006, the operation unit 1007, and the power source unit 1008 are connected to one another via a bus line 1009.

The lens group 1001 captures incident light (image light) from a subject and forms an image on an image pickup surface of the solid-state image pickup device 1002. The solid-state image pickup device 1002 corresponds to the solid-state image sensor according to the seventh embodiment of a CMOS image sensor described above. The solid-state image pickup device 1002 converts a light amount of the incident light imaged on the image pickup surface by the lens group 1001 into an electric signal in the pixel unit and supplies the electric signal to the DSP circuit 1003 as a pixel signal.

The DSP circuit 1003 executes predetermined image processing to the pixel signal supplied from the solid-state image pickup device 1002, supplies the pixel signal after image processing to a frame memory 1004 in the frame unit, and the pixel signal is temporarily stored in the frame memory 1004.

For example, the display unit 1005 is constituted of a panel type display device such as a liquid crystal panel or an organic EL (Electro Luminescence) panel, and displays an image on the basis of the pixel signals in the frame unit, temporarily stored in the frame memory 1004.

The recording unit 1006 consists of a DVD (Digital Versatile Disk), a flash memory, and the like, and read out and stores the pixel signal in the frame unit temporarily stored in the frame memory 1004.

The operation unit 1007 issues operation commands for various functions of the image pickup device 1000 on the basis of operations of a user. The power source unit 1008 appropriately supplies power supplies to the DSP circuit 1003, the frame memory 1004, the display unit 1005, the recording unit 1006, and the operation unit 1007.

The electronic device to which the present technique is applied may be any device using a CMOS image sensor in an image uptake unit (photoelectric conversion unit), and may be mobile terminal devices having an image pickup function, copiers using a CMOS image sensor in an image reader, and the like, in addition to the image pickup device 1000.

### Other Embodiments

While the present technique has been described above in the form of the first to seventh embodiments, it is not to be understood that the descriptions and drawings that constitute parts of the disclosure limit the present technique. When the purpose of the technical content disclosed by the above embodiments is understood, it will be clear for a person skilled in the art that various alternative embodiments, examples, and operable techniques are included in the present technique. Additionally, the configurations each disclosed in the first to seventh embodiments can be combined appropriately within the range where there is no contradiction.

Examples of applications of the present disclosure include infrared light-receiving elements, and image pickup devices and electronic devices using the same. Possible uses include normal cameras, smartphones, as well as a wide variety of applications of imaging and sensing, including surveillance cameras, cameras for industrial instruments such as for factory inspection, in-vehicle cameras, distance-measuring sensors (ToF sensors), infrared ray sensors, and the like. An example thereof is described below.

The present technique can also take on the following configurations.

(1) A semiconductor device including:

a semiconductor layer containing silicon,

a first insulating film that is disposed on the semiconductor layer and has an opening for exposing part of the semiconductor layer,

an electrically conductive layer that is filled in the opening of the first insulating film and has a lower edge that is in contact with the semiconductor layer, and an alteration layer that is disposed between the first insulating film and the electrically conductive layer and contains oxygen.

(2) The semiconductor device according to (1), wherein

the alteration layer has a thickness between the first insulating film and the electrically conductive layer becoming thinner toward the semiconductor layer.

(3) The semiconductor device according to (2), wherein

a lateral side surface of the alteration layer, the surface being in contact with the first insulating film, has a stepped shape.

(4) The semiconductor device according to (3), wherein

a difference in level of the stepped shape of a lower part of the alteration layer is smaller than a difference in level of the stepped shape of an upper part of the semiconductor layer.

(5) The semiconductor device according to any one of (1) to (4), wherein a relative permittivity of the alteration layer is lower than a relative permittivity of the first insulating film.

(6) The semiconductor device according to any one of (1) to (5), wherein the first insulating film is made of silicon nitride.

(7) The semiconductor device according to any one of (1) to (6), wherein the alteration layer contains silicon oxide or a silicon oxynitride.

(8) The semiconductor device according to any one of (1) to (7), further including:

a second insulating film disposed between the semiconductor layer and the first insulating film.

(9) The semiconductor device according to (8), wherein the second insulating film is made of silicon oxide.

(10) The semiconductor device according to any one of (1) to (9), further including:

a third insulating film disposed on the first insulating film.

(11) The semiconductor device according to (10), wherein the third insulating film is made of a silicon oxide film.

(12) An etching method including:

attracting and adhering a first polymerization film onto an insulating film disposed on a semiconductor layer that contains silicon by plasma of a first gas, removing the first polymerization film by plasma of a second gas, oxidizing an upper surface of the insulating film exposed by removing the first polymerization film to form an alteration layer,

attracting and adhering a second polymerization film onto the alteration layer by plasma of a third gas, and removing the second polymerization film and the alteration layer by plasma of a fourth gas.

(13) The etching method according to (12), wherein the first gas contains carbon, hydrogen, and fluorine.

(14) The etching method according to (12) or (13), wherein the second gas contains oxygen.

(15) The etching method according to any one of (12) to (14), wherein the third gas contains carbon and fluorine.

(16) The etching method according to any one of (12) to (15), wherein the fourth gas contains noble gas.

(17) The etching method according to any one of (12) to (16), further including, before adsorption on the first polymerization layer, removing an upper part of the first insulating film by dry etching.

(18) The etching method according to any one of (12) to (17), wherein cycles, each cycle including attracting and adhering the first polymerization film, forming the alteration layer, attracting and adhering the second polymerization film, and removing the alteration layer, are repeated plural numbers of times.

(19) The etching method according to (18), wherein plasma energy of the second gas is made identical in each cycle of the cycles repeated plural numbers of times.

(20) The etching method according to (18), wherein plasma energy of the second gas in the cycles of a latter half of the plural numbers of times is made smaller than plasma energy of the second gas in the cycles of a former half of the plural numbers of times.

### REFERENCE SIGNS LIST

1 Substrate
2 Pixel
3 Pixel domain (imaging domain)
4 Vertical drive circuit
5 Column signal processing circuit
6 Horizontal drive circuit
7 Output circuit
8 Control circuit
9 Vertical signal line
10 Horizontal signal line
11 Semiconductor layer
11a Oxidation layer
11b Recess part (recess)
11c Residual defect
12 Insulating film (lower layer insulating film)
12a Slit
13 Insulating film (middle layer insulating film)
13a Recess part
13b Upper part
14 Insulating film (upper layer insulating film)
14a Opening
15 Alteration layer (modified layer)
15a Upper part
15b Lower part
18 Electrically conductive layer
21 Processing container
22 Upper part electrode
22 Electrode
23 Lower part electrode
24 Gas supply unit
25 Control unit
26 Exhaust unit
27, 28 High frequency power source
31 Input and output terminal
100 Object to be processed
1000 Image pickup device
1001 Lens group
1002 Solid-state image pickup device
1003 DSP circuit
1004 Frame memory
1005 Display unit
1006 Recording unit
1007 Operation unit
1008 Power source unit
1009 Bus line

What is claimed is:

1. A semiconductor device comprising:
a semiconductor layer containing silicon,
a first insulating film that is disposed on the semiconductor layer and has an opening for exposing part of the semiconductor layer,
an electrically conductive layer that is filled in the opening of the first insulating film and has a lower edge that is in contact with the semiconductor layer, and
an alteration layer that is disposed between the first insulating film and the electrically conductive layer and contains oxygen.

2. The semiconductor device according to claim 1, wherein
the alteration layer has a thickness between the first insulating film and the electrically conductive layer becoming thinner toward the semiconductor layer.

3. The semiconductor device according to claim 2, wherein
a lateral side surface of the alteration layer, the surface being in contact with the first insulating film, has a stepped shape.

4. The semiconductor device according to claim 3, wherein
a difference in level of the stepped shape of a lower part of the alteration layer is smaller than a difference in level of the stepped shape of an upper part of the semiconductor layer.

5. The semiconductor device according to claim 1, wherein
a relative permittivity of the alteration layer is lower than a relative permittivity of the first insulating film.

6. The semiconductor device according to claim 1, wherein
the first insulating film is made of silicon nitride.

7. The semiconductor device according to claim 1, wherein
the alteration layer contains silicon oxide or a silicon oxynitride.

8. The semiconductor device according to claim 1, further comprising
a second insulating film disposed between the semiconductor layer and the first insulating film.

9. The semiconductor device according to claim 8, wherein
the second insulating film is made of silicon oxide.

10. The semiconductor device according to claim 1, further comprising
a third insulating film disposed on the first insulating film.

11. The semiconductor device according to claim 10, wherein
the third insulating film is made of a silicon oxide film.

12. An etching method, comprising:
attracting and adhering a first polymerization film onto an insulating film disposed on a semiconductor layer that contains silicon by plasma of a first gas,
removing the first polymerization film by plasma of a second gas, oxidizing an upper surface of the insulating film exposed by removing the first polymerization film to form an alteration layer,
attracting and adhering a second polymerization film onto the alteration layer by plasma of a third gas, and
removing the second polymerization film and the alteration layer by plasma of a fourth gas.

13. The etching method according to claim 12, wherein
the first gas contains carbon, hydrogen, and fluorine.

14. The etching method according to claim 12, wherein
the second gas contains oxygen.

15. The etching method according to claim 12, wherein
the third gas contains carbon and fluorine.

16. The etching method according to claim 12, wherein
the fourth gas contains noble gas.

17. The etching method according to claim 12, further comprising,
before adsorption on the first polymerization layer,
removing an upper part of the first insulating film by dry etching.

18. The etching method according to claim 12, wherein
cycles, each cycle including attracting and adhering the first polymerization film, forming the alteration layer, attracting and adhering the second polymerization film, and removing the alteration layer, are repeated plural numbers of times.

19. The etching method according to claim 18, wherein
plasma energy of the second gas is made identical in each cycle of the cycles repeated plural numbers of times.

20. The etching method according to claim 18, wherein
plasma energy of the second gas in the cycles of a latter half of the plural numbers of times is made smaller than plasma energy of the second gas in the cycles of a former half of the plural numbers of times.
